(19) United States
(12) Patent Application Publication
(10) Pub. No.: US 2023/0094592 A1
(43) Pub. Date: Mar. 30, 2023

(54) PROCESS FOR MANUFACTURING A VERTICAL CONDUCTION SILICON CARBIDE ELECTRONIC DEVICE AND VERTICAL CONDUCTION SILICON CARBIDE ELECTRONIC DEVICE HAVING IMPROVED MECHANICAL STABILITY

(71) Applicant: STMICROELECTRONICS S.r.l., Agrate Brianza (IT)

(72) Inventors: Paolo BADALA', Acireale (IT); Valentina SCUDERI, Catania (IT); Anna BASSI, Gravina di Catania (IT); Massimo BOSCAGLIA, San Giovanni La Punta (IT); Giovanni FRANCO, Viagrande (IT)

(73) Assignee: STMICROELECTRONICS S.r.l., Agrate Brianza (IT)

(21) Appl. No.: 17/949,057

(22) Filed: Sep. 20, 2022

(30) Foreign Application Priority Data
Sep. 30, 2021 (IT) 102021000025163

(51) Int. Cl. H01L 29/16; H01L 21/02; H01L 29/66; H01L 21/268

(52) U.S. Cl. CPC H01L 29/1608; H01L 21/02529; H01L 29/66068; H01L 21/268

(57) ABSTRACT

For the manufacturing of a vertical conduction silicon carbide electronic device, a work wafer, which has a silicon carbide substrate having a work face, is processed. A rough face is formed from the work face of the silicon carbide substrate. The rough face has a roughness higher than a threshold. A metal layer is deposited on the rough face and the metal layer is annealed, thereby causing the metal layer to react with the silicon carbide substrate, forming a silicide layer having a plurality of protrusions of silicide.

### BACKGROUND

### Technical Field

The present disclosure is relative to a process for manufacturing a vertical conduction silicon carbide electronic device and to a vertical conduction silicon carbide electronic device having improved mechanical stability.

### Description of the Related Art

As known, silicon carbide (SiC) electronic devices such as Junction Barrier Schottky (JBS) diodes, Merged PiN Schottky (MPS) diodes and MOSFET transistors, have better performances than silicon electronic devices, in particular for power applications, wherein high operating voltages or other specific operating conditions, such as high temperature, are employed.

A silicon carbide electronic device for power applications, hereinafter indicated as power device, comprises a silicon carbide body, a front metal region and a back metal region. In use, a current may flow through the silicon carbide body between the front metal region and the back metal region.

It is known to obtain the power device from a silicon carbide wafer having a front surface and a back surface, in one of its polytypes, such as 3C—SiC, 4H—SiC and 6H—SiC.

### BRIEF SUMMARY

The present disclosure provides a process for manufacturing a vertical conduction silicon carbide electronic device and a vertical conduction silicon carbide electronic device are provided.

### BRIEF DESCRIPTION OF THE SEVERAL VIEWS OF THE DRAWINGS

For a better understanding of the present disclosure, a non-limiting embodiment is now described, with reference to the attached drawings, wherein:

FIG. 1 shows a cross-section of a work body comprising a silicon carbide wafer, according to the present manufacturing process;

FIG. 2 is a top plan view of the work body of FIG. 1;

FIGS. 3-7 are cross-sections of the work body of FIG. 1 in subsequent manufacturing steps;

FIG. 8 is an exemplificative micrograph of a surface of the work body of FIG. 7;

FIG. 9 is an enlarged detail of the micrograph of FIG. 8;

FIG. 10 is a cross-section of the work body of FIG. 7 in a subsequent manufacturing step; and

FIG. 11 is a cross-section of the present electronic device.

### DETAILED DESCRIPTION

Devices like transistors, diodes, resistors, etc., are generally formed in the silicon carbide body from the front surface. Then, the front metal region is formed on the front surface to mutually interconnect the integrated devices as well as to allow connection of the power device with external circuit components and/or stages.

In addition, the back surface of the wafer is processed, so as to form the back metal region.

To this end, a metal layer, e.g., nickel or titanium, is deposited on the back surface.

Then, a laser beam is used to heat the metal layer and cause the metal layer to fully react with the silicon carbide of the wafer, thereby forming a silicide layer, e.g., titanium or nickel silicide.

Subsequently, a metallization layer is deposited on the silicide layer.

After final manufacturing steps including dicing, the power device is obtained.

The inventors have verified that, in some existing solutions, the silicide layer of power devices has a low mechanical stability. For example, during some reliability tests of the existing devices, the inventors have observed that the silicide layer has a high probability of delamination from the silicon carbide body or mechanical fracture, thereby causing failure of the power device.

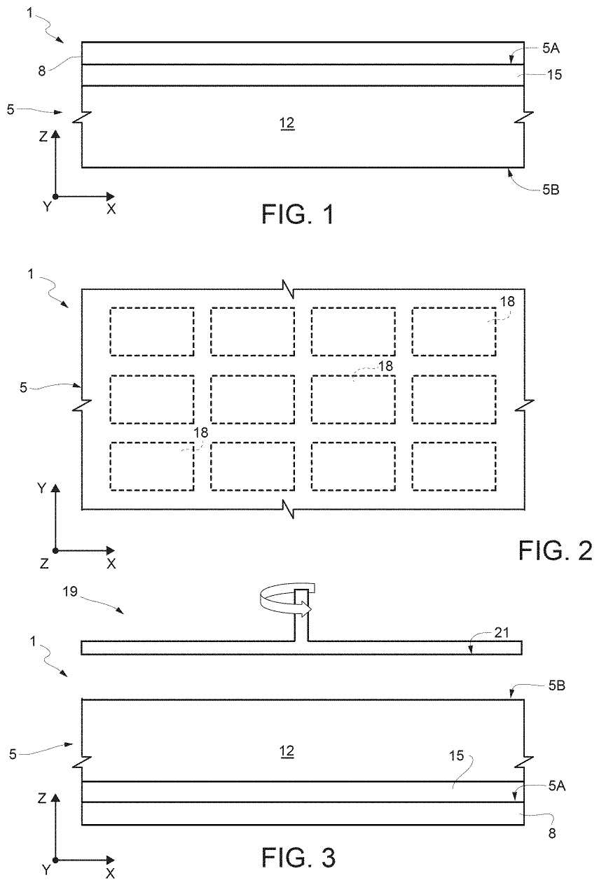

FIGS. 1 and 2 show a work body 1 in a Cartesian reference system XYZ comprising a first axis X, a second axis Y and a third axis Z.

The work body 1 has already been subject to initial manufacturing steps.

The work body 1 is formed by a wafer 5 of silicon carbide (SiC) in one of its polytypes, such as 3C—SiC, 4H—SiC and 6H—SiC, having a first surface 5A and a second surface 5B, and by a connection structure layer 8 extending on the first surface 5A of the wafer 5.

The wafer 5 comprises a work substrate 12, which forms the second surface 5B of the wafer 5 and has a thickness comprised for example between 275 μm and 375 μm, for example of about 350 μm, and a device layer 15, which forms the first surface 5A of the wafer 5 and extends directly on the work substrate 12.

The device layer 15 may be a portion of the work substrate 12 or may be an epitaxial layer grown on the work substrate 12.

The device layer 15 comprises current conduction zones, here not shown, whose structure, number and configuration depend on the specific application.

For example, the device layer 15 may comprise a drift layer and one or more implanted regions which may form, for example, source regions and body regions, depending on the specific application, examples whereof are shown for illustrative purposes in FIG. 11.

In an embodiment, the device layer 15 may also comprise gate structures. In an embodiment, the device layer 15 may be a multilayer, with different device structures integrated in the various layers.

The connection structure layer 8 comprises one or more metal layers that form an electrical interconnect structure for the device layer 15.

According to an embodiment, the connection structure layer 8 may also comprise one or more layers of insulating materials, forming passivation structures.

The device layer 15 and the connection structure layer 8 form at least one die portion, here a plurality of die portions 18.

Each die portion 18 is intended to form a respective electronic device, after dicing the work body 1.

Each die portion 18 has a die area, which occupies a respective portion of the area of the first surface 5A of the wafer 5.

In FIG. 2, for simplicity, the die portions 18 are schematically indicated by dashed lines.

For example, in this embodiment, each die portion 18 has a rectangular shape in top plan view. By way of example only, the die area may be approximately of few millimeters squared, for example approximately 4 mm by 5 mm.

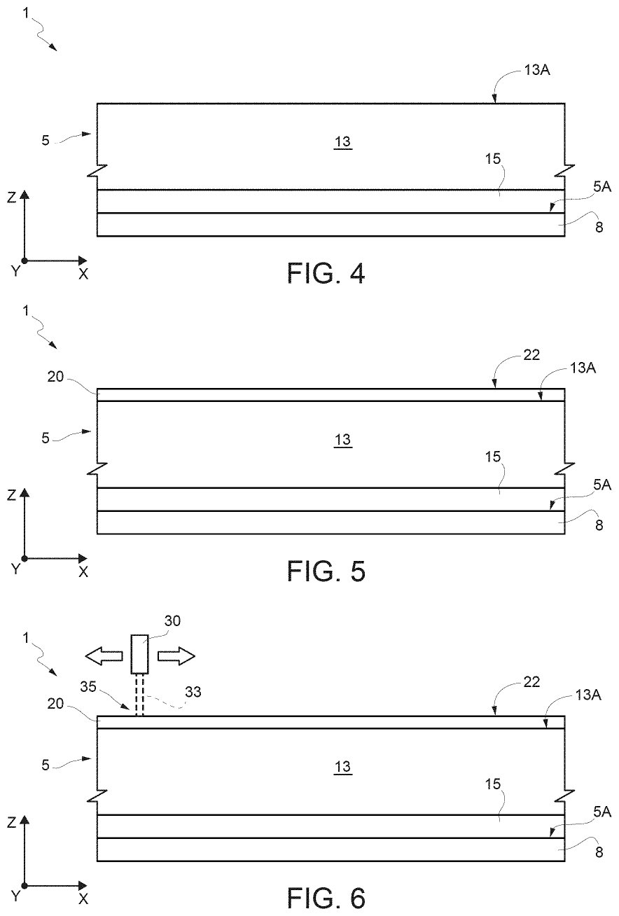

Subsequently, as shown in FIGS. 3 and 4, the work substrate 12 undergoes a thinning step, thereby forming a thinned substrate 13 having a rough surface 13A.

In an embodiment, as shown in FIG. 3, the work body 1 is flipped upside down and the work substrate 12 is thinned from the second surface 5B of the wafer 5.

However, the work substrate 12 may be thinned without flipping the work body 1 upside down, for example depending on the specific machinery used in the thinning step.

For example, here, the second surface 5B of the wafer 5 undergoes grinding by using a grinding wheel 19 having an abrasive surface 21.

The work substrate 12 is thinned by applying a friction between the abrasive surface 21 and the second surface 5B of the wafer 5, for example here by applying a relative rotation between the grinding wheel 19 and the work body 1 around an axis parallel to the third axis Z.

FIG. 4 shows the work body 1 after thinning of the work substrate 12 and therefore the formation of the thinned substrate 13.

The thinned substrate 13 has a thickness comprised, for example, between 100 μm and 250 μm, for example of about 180 μm, and extends between the device layer 15 and the rough surface 13A.

In some embodiments, after the thinning step, the rough surface 13A of the thinned substrate 13 forms the second surface of the wafer 5, which is therefore also indicated by 13A.

The rough surface 13A has a roughness, for example measurable in a known way by an Atomic Force Microscopy (AFM), having a root mean square value (RMS) which is equal to or higher than 30 nm, for example comprised between 30 nm and 100 nm.

The abrasive surface 21 of the grinding wheel 19 is specifically chosen, at the design stage, so to obtain said roughness of the rough surface 13A. For example, the abrasive surface 21 is chosen to have a coarse mesh, with mesh size comprised, for example, between 500 and 1500, for example of about 1000. The abrasive surface 21 comprises in fact abrasive grains; a higher mesh size indicates a smaller size of the abrasive grains and may be used to obtain a smaller roughness of the rough surface 13A.

Then, FIG. 5, a contact layer 20 is deposited on the rough surface 13A, forming a contact surface 22 of the work body 1.

The contact layer 20 is a metal material such as nickel, titanium or an alloy of nickel and silicon, and has a thickness, measured parallel to the third axis Z, comprised for example between 10 nm and 200 nm, for example of about 100 nm.

Subsequently, FIG. 6, the work body 1, for example the contact layer 20, undergoes an annealing step, for example, a laser annealing.

For example, a laser source 30 is used to generate a light beam 33 and focus the light beam 33 on the contact surface 22.

The light beam 33 has an energy density higher than 3 J/cm², for example comprised between 3.0 J/cm² and 4.4 J/cm², for example of 3.8 J/cm².

The light beam 33 has a wavelength comprised, for example, between 290 nm and 370 nm, for example of 310 nm.

The light beam 33 may be a pulsed light beam wherein each laser pulse has a duration comprised, for example, between 100 ns and 300 ns, for example of 160 ns.

The light beam 33 has a beam footprint 35 on the contact surface 22.

The beam footprint 35 may form a polygonal shape, a circular shape or any other shape, for example a squared shape, on the contact surface 22.

During the annealing step, the laser source 30 focuses the laser beam 33 on the contact surface 22, i.e., the beam footprint 35 forms an irradiated portion of the contact surface 22.

For example, each portion of the contact surface 22 may be irradiated by one or more pulses or shots of the laser beam 33, for example comprised between one and five.

The laser beam 33 is absorbed by the contact layer 20 and by part of the thinned substrate 13. The absorbed light generates heat locally, i.e., immediately under the irradiated portion of the contact surface 22, for example to a depth of few microns from the contact surface 22.

The generated heat makes the contact layer 20 and the thinned substrate 13 to react locally, at a respective portion of the rough surface 13A, forming a silicide, for example nickel silicide or titanium silicide.

According to an embodiment, the beam footprint 35 may have an area much smaller than the contact surface 22.

For example, the beam footprint 35 may have a side, in the case of squared shape, comprised, for example, between 8 mm and 36 mm, for example may be about 10 mm.

Therefore, in order to cause the reaction of the entire contact layer 20 with the thinned substrate 13, the contact surface 22 may be scanned using a step-and-repeat approach.

The contact surface 22 may be scanned by moving the beam footprint 35, between two adjacent irradiated portions of the contact surface 22, by a step that is approximately equal to the side of the beam footprint 35.

For example, at a first approximation, the beam footprint 35 may be moved, with respect to contact surface 22, so that there is no overlap between two adjacent irradiated portions of the contact surface 22. Accordingly, the throughput of the laser annealing step may be maximized.

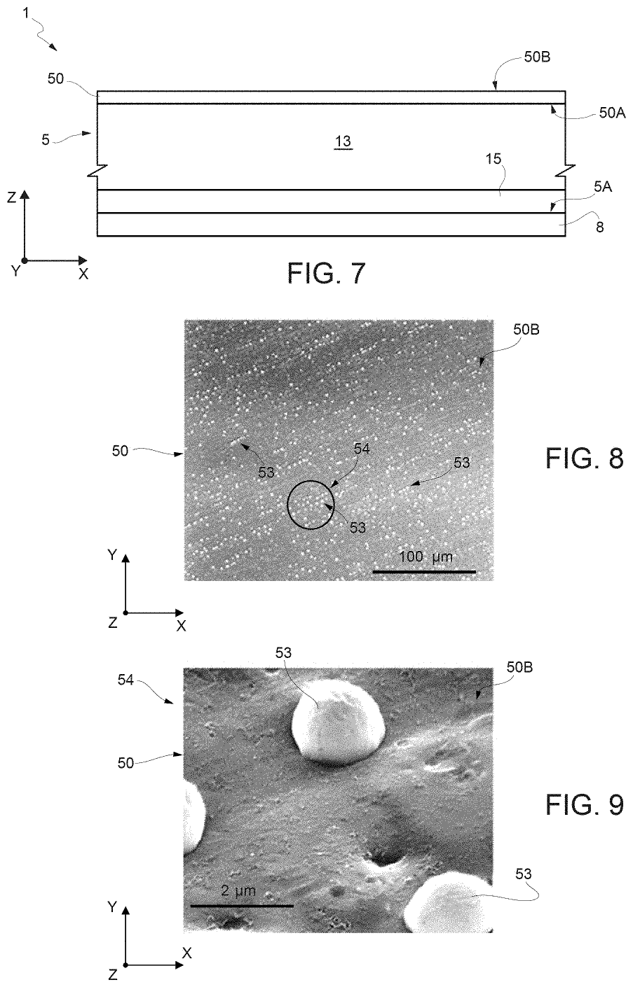

FIG. 7 shows the work body 1 after the contact surface 22 has been completely exposed by the laser beam 33, thereby causing the complete reaction of the contact layer 20 with the thinned substrate 13 and formation of an ohmic layer 50.

The ohmic layer 50 is of silicide and extends between a first surface 50A, which corresponds to the rough surface 13A, and a second surface 50B, which corresponds to the contact surface 22.

The ohmic layer 50 may be thicker than the contact layer 20, since also part of the thinned substrate 13 has reacted to form the ohmic layer 50.

FIG. 8 is an example micrograph of a portion of the second surface 50B of the ohmic layer 50.

The second surface 50B of the ohmic layer 50 comprises a plurality of protrusions 53, of silicide, which are visible in FIG. 8 as bright spots on the second surface 50B of the ohmic layer 50.

FIG. 9 is a zoomed-in micrograph of part of an area 54 of the second surface 50B of the ohmic layer 50 identified by a circle in FIG. 8.

The protrusions 53 substantially have each a spherical shape and a diameter comprised, for example, between 0.5 μm and 2 μm, for example between 1 μm and 2 μm.

However, the protrusions 53 may have a different shape and each have a height, measured parallel to the third axis Z, and/or a width, measured parallel to the first axis X and/or the second axis Y, which is comprised between 0.5 μm and 2 μm, for example between 1 μm and 2 μm.

The protrusions 53 have a density on the second surface 50B of the ohmic layer 50 that is higher than 2000 protrusions/mm², for example comprised between 2000 protrusions/mm² and 20000 protrusions/mm².

The density and the distribution of the protrusions 53 depends on the roughness of the rough surface 13A. For example, the protrusions 53 may be randomly distributed on the second surface 50B of the ohmic layer 50 or may have a specific distribution, depending on the machinery and parameters used during the thinning step.

Moreover, the size of the protrusions 53 may be adjusted by tuning the roughness of the rough surface 13A, the thickness of the contact layer 20, and the parameters of the annealing step, e.g., on the parameters of the laser beam 33.

The roughness of the rough surface 13A enhances an uneven nucleation of the atoms during the silicide reaction between the contact layer 20 and the thinned substrate 13, i.e., during the annealing step, thereby forming the protrusions 53 of silicide.

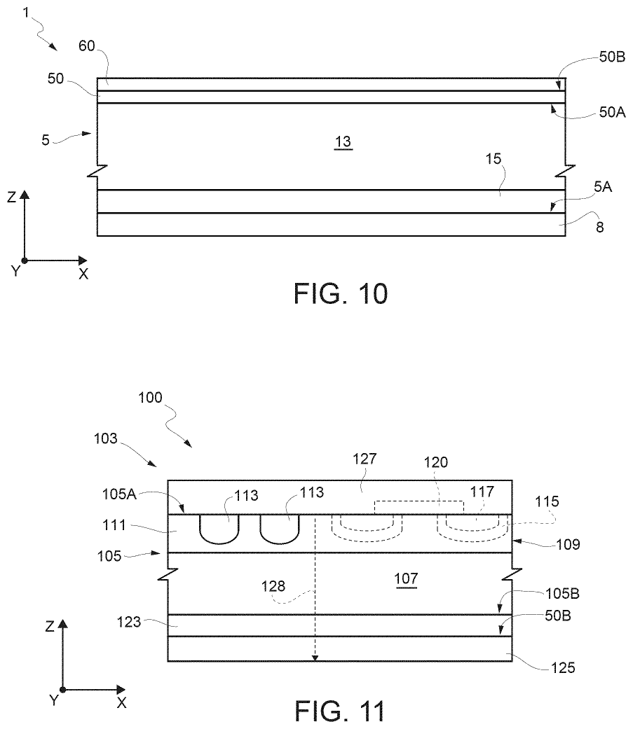

In FIG. 10, a metallization layer 60 is deposited on the second surface 50B of the ohmic layer 50. The metallization layer 60 may be a single metal layer or a stack of different metal layers, for example Ti/NiV/Ag.

The metallization layer 60 is useful for subsequent manufacturing steps, for example assembling processes such as sintering and diffusion soldering.

The work body 1 is then subject to known final manufacturing steps, such as dicing, thereby forming an electronic device 100 (FIG. 11) for each die portion 18.

The electronic device 100 comprises a die 103 including a body 105 having a first surface 105A, which corresponds to the first surface 5A of the wafer 5, and a second surface 105B, which corresponds to the first surface 50A of the ohmic layer 50.

The body 105 comprises a substrate 107 (corresponding to the thinned substrate 13 and forming the second surface 105B) and a device region 109 (corresponding to the device layer 15 and forming the first surface 105A).

The device region 109, as discussed above for the device layer 15, accommodates functional regions of various kind and dimensions, according to the specific type of the electronic device 100 and the specific application.

By way of example, the electronic device 100 may be a JBS or an MPS diode. In this case, as shown in FIG. 11 by way of example, the device region 109 forms a drift region 111 of a first conductivity type, e.g., N-type, accommodating two implanted regions 113 of a second conductivity type, e.g., P-type.

In some embodiments, as also shown as an example in FIG. 11, the electronic device 100 may be a MOSFET device. In this case, the drift region 111 accommodates body regions 115 of the second conductivity type, source regions 117 of the first conductivity type and insulated gate regions 120 of dielectric material (represented with dashed lines in FIG. 11).

The die 103 comprises an ohmic connection region 123, corresponding to the ohmic layer 50, extending on the second surface 105B of the body 105 and forming a metallization contact surface, which corresponds to the second surface 50B of the ohmic layer 50 and therefore it is indicated by the same reference number.

The die 103 also comprises a back metallization region 125 corresponding to the metallization layer 60 and extending on the metallization contact surface 50B.

The die 103 further comprises a connection structure region 127 corresponding to the connection structure layer 8, extending on the first surface 105A of the body 105.

For example, the device region 109 and the connection structure region 127 correspond to a respective die portion 18 (FIG. 2).

In some embodiments, the electronic device 100 has a current path 128, schematically represented by a dashed arrow in FIG. 11, which extends between the connection structure region 111 and the back metallization region 125, through the body 105.

In some embodiments, a current may flow through the current path 128, depending on the specific structure of the device region 109, i.e., on the type of the electronic device 100.

The ohmic connection region 123 shows a high mechanical stability.

The ohmic connection region 123 comprises, on the second surface 50B, the protrusions 53 described with reference to FIGS. 8 and 9, the number thereof being a function of the area of the second surface 50B of the ohmic connection region 123 and the density of the protrusions 53.

For example, by considering the density of the protrusions 53 to be 2000 protrusions/mm² and the area of the second surface 50B of the ohmic connection region 123 to be, by way of example only, about 10 mm², the second surface 50B of the ohmic connection region 123 has a number of protrusions approximately equal to 2·10⁴.

The inventors has verified that the protrusions 53 work as anchoring regions of the ohmic connection region 123, thereby increasing the mechanical robustness thereof. The electronic device 100 is therefore less subject to mechanical defects such as fracture and delamination of the ohmic connection region 123.

For example, a shear test of the electronic device 100, performed by the Applicant, shows an average increase of the shear strength of the electronic device 100 of about 24% with respect to a case wherein the electronic device 100 has been manufactured without forming the rough surface 13A.

Moreover, a shear test of the electronic device 100, performed by the Applicant after subjecting test devices to one hundred thermal cycles, shows an average increase of the shear strength of the electronic device 100 up to 99% with respect to the case wherein the electronic device 100 has been manufactured without forming the rough surface 13A.

At the same time, the ohmic connection region 123 ensures a good electrical contact, for example an ohmic contact, with the substrate 107. Therefore, the electronic device 100 also maintains good electrical properties.

Moreover, the fact that the substrate 107 is thin, e.g., comprised between 100 μm and 250 μm, for example is of about 180 μm, and the presence of the protrusions 53 allow to reduce the on-resistance of the current path 128. Therefore, the electronic device 100 has a low power consumption.

In addition, it is possible to optimize the throughput of the laser annealing step of FIG. 6, i.e., by scanning the contact surface 22 without overlapping adjacent irradiated portions of the contact surface 22. Accordingly, the manufacturing costs of the electronic device 100 may be kept low.

It should be noted that wafer substrate thinning, by mechanical grinding of hundreds of microns of substrate material in reasonable process time, usually requires the use of a grinding wheel with abrasive grain of large size. This leaves a highly constrained layer on the backside of the wafer, causing high levels of bow and warpage on the wafer, which make the handling of the wafer difficult in subsequent manufacturing process steps. Thus, in conventional wafer thinning, a second grinding wheel is used, with abrasive grain of smaller size, that results in a smooth, weakly strained backside surface. For silicon substrate wafers, a further chemical attack is conventionally performed of the wafer backside to remove a portion of the residual strained top layer and reduce even more the wafer backside roughness and wafer bow/warpage. However, there is no convenient chemistry for silicon carbide wafer substrates, so the second grinding wheel grain size and grinding process parameters are chosen to achieve a smooth wafer backside, of root mean square value (RMS) which is typically lower than 10 nm, for example comprised between 10 nm and 3 nm.

Although a smooth, low constraint level wafer backside is desirable for wafer handling, the inventors discovered that, surprisingly, keeping a rough backside surface highly increases the mechanical robustness of the ohmic region and its adhesion to the silicon carbide substrate. At the expense of a little bit more difficult wafer handling, still deemed acceptable, this can solve the fracture and delamination issues associated with ohmic region in vertically integrated power devices formed on silicon carbide substrate.

It is clear that the present manufacturing method and the corresponding electronic device may be subject to modifications and variations without departing the scope of the present disclosure, as defined in the attached claims.

The rough surface 13A may be obtained by increasing the roughness of the second surface 5B of the wafer 5 without thinning of the work substrate 12, for example through other specific chemical and/or physical surface treatments.

The thinning step of the work substrate 12 may be performed through a process different from grinding, for example laser cutting, designed to obtain the thinned substrate 13 having the rough surface 13A.

A process for manufacturing a vertical conduction silicon carbide electronic device from a work wafer (5) including a silicon carbide substrate (12) having a work face (5B), the process may be summarized as including forming a rough face (13A) from the work face of the silicon carbide substrate, the rough face having a roughness higher than a threshold; depositing, on the rough face, a metal layer (20); and annealing the metal layer, thereby causing the metal layer to react with the silicon carbide substrate, forming a silicide layer (50) having a plurality of protrusions (53) of silicide.

The threshold may be a root mean square value of the roughness of the rough face (13A), the root mean square value being equal to or higher than 30 nm.

Forming a rough face (13A) may include thinning the silicon carbide substrate (12) from the work face (5B), thereby forming a thinned layer (13) having the rough face (13A).

The thinned layer (13) may be formed by grinding the silicon carbide substrate, on the work face, with an abrasive surface (21).

The abrasive surface may have a mesh size between 1500 and 500.

The thinned layer (13) may have a thickness between 100 μm and 250 μm.

The metal layer (20) may have a contact face (22) and annealing the metal layer may include laser annealing the contact face of the metal layer with a laser beam (33).

The laser beam (33) may have a footprint (35) smaller than the contact face and laser annealing may include scanning the entire contact face (22) with the laser beam (33) using a step-and-repeat type of scanning.

The laser beam (33) may have a footprint (35) on the contact face (22), laser annealing the contact face may include scanning the contact face so that two adjacent irradiated portions of the contact face have approximately zero mutual overlap.

The laser beam (33) may have an energy density higher than 3 J/cm2.

The process may further include depositing a metallization layer (60) on the silicide layer (50).

A vertical conduction silicon carbide electronic device formed in a die (103) may be summarized as including a body (105, 107) of silicon carbide; and a contact region (123) of silicide extending on the body and forming a connection surface (50B), wherein the contact region includes a plurality of protrusions (53) of silicide, the plurality of protrusions having a density, on the connection surface, that is higher than a threshold.

The threshold may be about 2000 protrusions/mm2.

Each protrusion may have a size between 0.5 μm and 2 μm.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a vertical conduction silicon carbide electronic device, the method comprising:
forming a rough face from a first face of a silicon carbide substrate, the rough face having a roughness higher than a threshold;
depositing, on the rough face, a metal layer; and
forming a silicide layer by annealing the metal layer, the silicide layer having a plurality of protrusions of silicide.

2. The method according to claim 1, wherein the threshold is a root mean square value of a roughness of the rough face, the root mean square value being equal to or higher than 30 nm.

3. The method according to claim 1, wherein the forming the rough face comprises thinning the silicon carbide substrate from the first face, thereby forming a thinned layer having the rough face.

4. The method according to claim 3, wherein the forming the rough face includes grinding the thinned layer of the silicon carbide substrate, on the first face, with an abrasive surface.

5. The method according to claim 4, wherein the abrasive surface has a mesh size between about 1500 and about 500.

6. The method according to claim 3, wherein the thinned layer has a thickness between about 100 μm and about 250 μm.

7. The method according to claim 1, wherein the metal layer has a contact face and the annealing the metal layer includes laser annealing the contact face of the metal layer with a laser beam.

8. The method according to claim 7, wherein the laser beam has a footprint smaller than the contact face and the laser annealing includes scanning entire contact face with the laser beam using a step-and-repeat type of scanning.

9. The method according to claim 7, wherein the laser beam has a footprint on the contact face, and the laser annealing the contact face includes scanning the contact face so that two adjacent irradiated portions of the contact face have approximately zero mutual overlap.

10. The method according to claim 7, wherein the laser beam has an energy density higher than 3 J/cm2.

11. The method according to claim 1, further comprising depositing a metallization layer on the silicide layer.

12. A vertical conduction silicon carbide electronic device, comprising:
a body of silicon carbide; and
a contact region of silicide on the body, the contact region including a connection surface,
wherein the contact region includes a plurality of first protrusions of silicide on the connection surface, the plurality of first protrusions having a density that is higher than a threshold.

13. The device according to claim 12, wherein the threshold is about 2000 protrusions/mm².

14. The device according to claim 12, wherein each first protrusion of the plurality of first protrusions has a size between about 0.5 μm and about 2 μm.

15. The device according to claim 12, comprising a metallization layer on the contact region.

16. The device according to claim 12, wherein the body includes a plurality of second protrusions on a surface of the body that interfaces with the contact region.

17. The device according to claim 12, further comprising a drift layer on a side of the body opposite to the contact region.

18. The device according to claim 17, further comprising a connection structure on the drift layer.

19. A structure, comprising:
a silicon carbide body, the silicon carbide body including a first surface and a second surface opposite to the first surface, the second surface including a plurality of first protrusions;
a silicide layer on the second surface; and
a drift layer on the first surface.

20. The structure of claim 19, wherein the silicide layer including a plurality of second protrusions on a surface of the silicide layer that is distal to the silicon carbide body.
